(19) United States
(12) Patent Application Publication
(10) Pub. No.: US 2007/0148955 A1
(43) Pub. Date: Jun. 28, 2007

(54) METHOD FOR FORMING METAL LINES IN A SEMICONDUCTOR DEVICE

(76) Inventor: Jae-Won Han, Seoul (KR)

Correspondence Address: SHERR & NOURSE, PLLC, 620 HERNDON PARKWAY, SUITE 200, HERNDON, VA, 20170, US

(21) Appl. No.: 11/616,268

(22) Filed: Dec. 26, 2006

(30) Foreign Application Priority Data
Dec. 28, 2005 (KR) 10-2005-0131508

(51) Int. Cl. H01L 21/4763

(52) U.S. Cl. 438/618

(57) ABSTRACT

A method for forming metal lines in a semiconductor device includes forming a first insulating film having a via hole over a semiconductor substrate with a conductive layer, forming a via metal line for filling the via hole, forming, over the first insulating film, a second insulating film having a trench, the trench having a larger width than that of the via hole, and forming a trench metal line for filling the trench. The second insulating film is made of a low-K material including SiOC, and the first insulating film is made of a different material from the second insulating film.

The present application claims priority under 35 U.S.C. 119 and 35 U.S.C. 365 to Korean Patent Application No. 10-2005-0131508 (filed on Dec. 28, 2005), which is hereby incorporated by reference in its entirety.

### BACKGROUND

Generally, metal lines within semiconductor devices are formed by using thin metal films made of Al or Cu etc., and connections between the semiconductor devices allow the circuits formed within semiconductor substrates to be connected to each other.

Metal lines for connecting device electrodes and pads separated by an insulating film such as an oxide film or the like may be formed through a dual damascene process including the steps of: selectively etching the insulating film to form a via hole, filling an inside of the via hole with a photoresist film, forming a trench pattern in the photoresist film over the insulating film, etching the insulating film to form a trench by using the trench pattern as a mask, removing the trench pattern and the filling film, and filling the inside of the via hole and the inside of the trench with the metal film.

A plurality of metal lines formed using the dual damascene process described above may be formed in a multiple layered structure. In this structure, there are parasitic capacitances between metal lines in adjacent layers, and parasitic capacitances between neighboring metal lines within layers. These parasitic capacitances cause a decrease in the operational speed of semiconductor devices.

Accordingly, in order to reduce the parasitic capacitances, the insulating film surrounding and supporting the metal lines may be made of a low-K material, having a relatively low dielectric constant.

Meanwhile, photoresist film for filling the via hole has an etching selectivity which is lower than that of the insulating film. That is, if the insulating film and the photoresist film are etched simultaneously for a predetermined time, the photoresist film will be etched less than the insulating film. As a result, fence defects are formed on a lower surface of the trench due to the difference in the etching selectivity between the insulating film and the photoresist film. The height of the fences may be lowered by a process for removing the photoresist film positioned within the via hole, but the fences may not be completely removed.

Accordingly, when the trench and the via hole are filled with a thin metal film, a height difference generated by the fences may cause the trench and the via hole to be incompletely filled with the thin metal film. A crack may develop in the metal lines. For this reason, the resistance of the metal lines may be increased, and the characteristics of the semiconductor device may be deteriorated degrading its reliability.

Also, residues generated by performing the etching process of the low-k material two times are left on the inside walls of the via hole and the trench. The residues increase the resistance and decrease the operational speed of the semiconductor device.

Also, when the low-K material is patterned through the dual damascene process, the low-K material exposed by performing the asher process and an asher liquid are chemically reacted to increase the dielectric constant (K) of the low-K material. As a result, the operational speed of the semiconductor device may be lowered.

### SUMMARY

Embodiments relate to a method for forming metal lines of a semiconductor device.

Embodiments relate to a method for manufacturing a semiconductor capable of reducing the dielectric constant (K) of an inter-metal insulating film and the generated residues thereby improving the operational speed of the semiconductor device.

Embodiments relate to a method for forming metal lines of a semiconductor device including the steps of: forming first insulating film having a via hole over a semiconductor substrate having a conductive layer; forming a via metal line for filling the via hole; forming, over the first insulating film, a second insulating film having a trench, the trench having a larger width than that of the via hole; and forming a trench metal line for filling the trench, wherein the second insulating film is made of a low-K material including SiOC, and the first insulating film is made of a different material from the second insulating film.

### BRIEF DESCRIPTION OF THE DRAWINGS

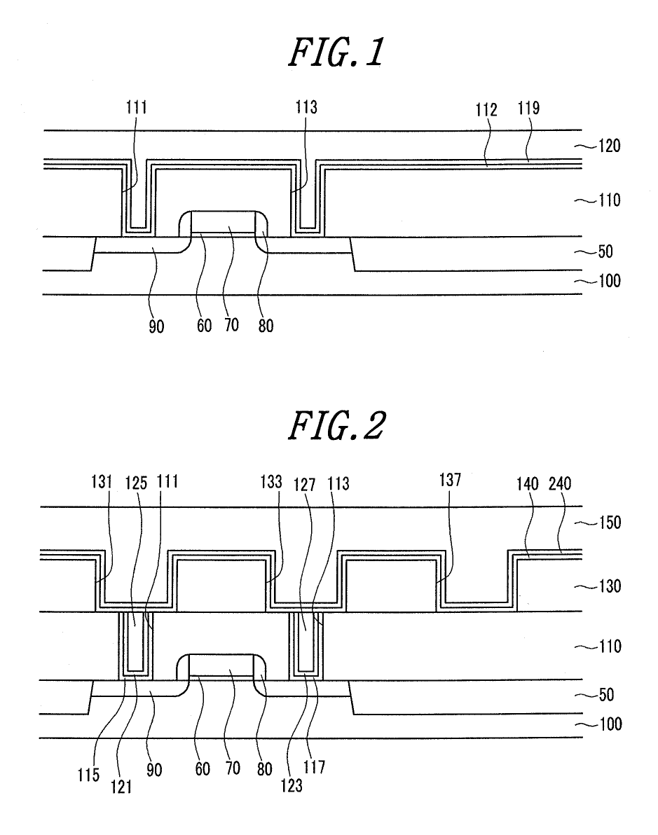

Example FIGS. 1 to 5 are views illustrating a method for manufacturing a semiconductor device in a sequence of manufacturing processes in accordance with embodiments.

### DETAILED DESCRIPTION

In the drawings, in order to represent various layers and regions in a clear manner, their thicknesses are represented to be enlarged. Through the entire specification, like elements are designated by the same reference numerals. If a portion such as a layer, a film, a region or a plate is referred to be positioned on another portion, such an expression may incorporate a case in which there exists still another portion therebetween as well as a case in which the portion is positioned right on said another portion. On the contrary, if a portion is referred to be positioned right on another portion, it means that there is no still another portion therebetween.

Hereinafter, a method for forming metal lines of a semiconductor device in accordance with embodiments will be described with reference to the accompanying drawings.

As shown in FIG. 1, a gate insulating film 60 and a gate electrode 70 are sequentially formed over a semiconductor substrate 100 in which a device isolating film 50 is formed. Spacers 80 are formed over sidewalls of the gate insulating film 60 and the gate electrode 70. A high concentration of impurity ions is implanted into an exposed part of the semiconductor substrate 100 with spacers 80 and gate electrode 70 acting as a mask, thereby forming high concentration junction regions 90. A lower interlayer insulating film 110 having lower via holes 111 and 113 for exposing the high concentration junction regions 90 therethrough is formed over an entire surface of a resultant upper structure of the semiconductor substrate 100. An ashing process is performed on a resultant upper structure of the semiconductor substrate 100. A lower via barrier film 112 is formed over the lower interlayer insulating film 110 and parts of the semiconductor substrate 100 exposed by the via holes 111, 113. A lower via seed film 119 is formed over the lower via barrier film 112 and a first metal thin film 120 is formed over the lower via seed film 119. The lower interlayer insulating film 110 may be made of FSG(fluoride-doped silicate glass), PSG(phosphorous-doped silicate glass), USG(undoped silicate glass), BPSG(boron phosphorous doped silicate glass), silicon oxide material, etc., and may have a thickness of about 1,000 Å

Then, as shown in FIG. 2, a chemical mechanical polishing (CMP) is carried out to remove portions of the lower via barrier film 112, a lower via seed film 119, and the first metal thin film 120 which are positioned over the top of the lower interlayer insulating film 110. The planarization process completes the lower via metal lines 125 and 127. At this point, the lower via barrier films 115 and 117 and the lower via seed films 121 and 123 remain only over the inside walls of the lower via holes 111 and 113.

Subsequently, over the entire surface of the resultant structure of the semiconductor substrate 100, a lower wiring insulating film 130 is formed to have lower trenches 131 and 133 for exposing a portion of the lower interlayer insulating film 110 and for respectively exposing the lower via metal lines 125 and 127, and a trench 137 for exposing a portion of the lower interlayer insulating film 110. Then, the ashing process is performed over the resultant surface structure of the semiconductor substrate 100. Subsequently, a lower trench barrier layer 140 is formed over the lower wiring insulating film 130, the lower via metal lines 125, 127 and the exposed part of the lower interlayer insulating film 110. A lower trench seed layer 240 and a second metal thin film 150 is subsequently formed over the lower trench barrier layer 140. The lower wiring insulating film 130 may be made of low-K material, for example, SiOC.

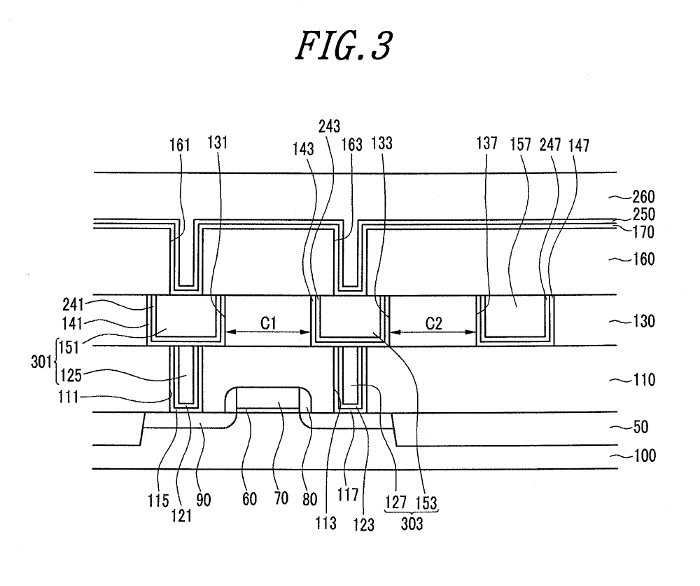

Then, as shown in FIG. 3, a CMP process removes portions of the lower trench barrier film 140, the lower trench seed film 240 and the second metal thin film 150 which are located over the top of the lower wiring insulating film 130. The planarization process completes lower trench metal lines 151, 153, and 157.

Two neighboring lower trench metal lines of the lower trench metal lines 151, 153 and 157 have parasitic capacitances C1 and C2. However, as described above, since low-K dielectric materials are used between the neighboring lower trench metal lines 151, 153 and 157, parasitic capacitances C1 and C2 are reduced and the operation of the semiconductor device is affected little.

The lower trench barrier films 141, 143, 147 and the lower trench seed films 241, 243, 247 remain only over the inside walls of the lower trenches 131, 133 and 137. The lower trench metal lines 151, 153 and the lower via metal lines 125, 127 are electrically connected to each other to form lower metal lines 300 and 303, respectively.

As described above, unlike the other alternatives in which the dual damascene process is used to form the lower metal line, the single damascene process is used to form the lower via metal lines 125 and 127 and then the lower trench metal lines 151, 153 are formed in accordance with embodiments.

In other words, the embodiments do not employ a dual damascene process where the inside of the via hole is filled with the photoresist film and a trench is formed. Therefore, the fences which could be formed due to the difference in the etching selectivity between the insulating film and the photoresist film filling the via hole are not formed over the bottom of the trench. Further, byproducts which could be generated by the removal of the photoresist film filling the inside of the via hole are not formed on the inside of the lower via holes 111, 113 and the lower trenches 131, 133. Accordingly, the lower via holes 111, 113 and the lower trenches 131, 133 can be fully filled with the first and the second metal thin films 120 and 150 respectively, so that the electrical characteristics of the semiconductor device and the reliability thereof may be improved.

Also, as described above, the lower interlayer insulating film 110 for surrounding and supporting the lower via metal lines 125 and 127 is made of SiO₂, FSG or the like and the lower wiring insulating film 130 for surrounding and supporting the lower trench metal lines 151, 153 is made of the low-K material. Accordingly, it is possible to suppress an increase in the dielectric constant (K) due to the chemical reaction of the low-K material and the asher liquid as the ashing process is performed over the low-K material in which the via holes and the trenches are exposed, thereby preventing the operational speed of the semiconductor device from being decreased.

Then, an upper interlayer insulating film 160 which has upper via holes 161 and 163 for partially exposing the lower trench metal lines 151 and 153 is formed over the lower wiring insulating film 130 and the lower trench metal lines 151, 153 and 157. An ashing process is performed over the resultant upper structure of the semiconductor substrate 100 and then an upper via barrier film 170 is formed over the upper interlayer insulating film 160 and the exposed lower trench metal lines 151 and 153. An upper via seed film 250 and a third metal thin film 260 is subsequently formed over the upper via barrier film 170. The upper interlayer insulating film 160 may be made of the same material as the lower interlayer insulating film 110, for example FSG(fluoride-doped silicate glass), PSG(phosphorous-doped silicate glass), USG(undoped silicate glass), BPSG(boron phosphorous doped silicate glass), or silicon oxide material etc. and have a thickness of about 1,000 Å or more.

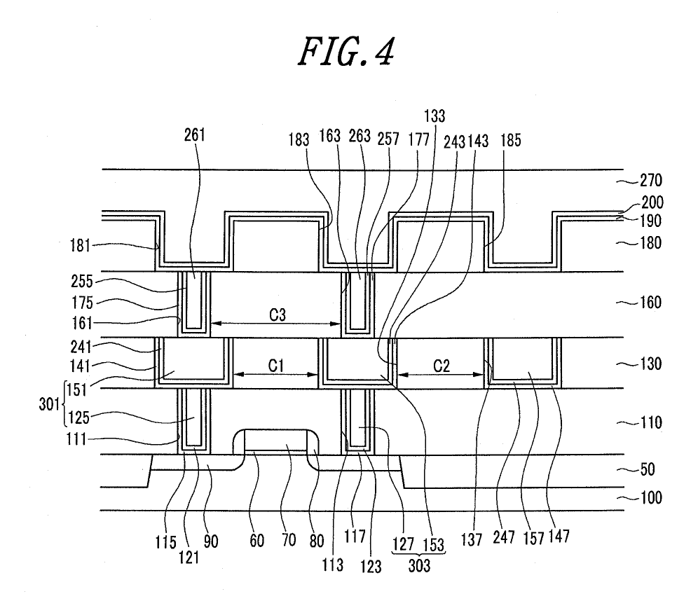

Then, as shown in FIG. 4, the CMP is carried out to remove the portions of the upper via barrier film 170, the upper via seed film 250 and the third metal thin film 260 which are positioned over the top of the upper interlayer insulating film 160. The planarization process completes the upper via metal lines 261 and 263.

The neighboring the upper via metal lines 261 and 263 have a parasitic capacitance C3. However, since the distance between the upper via metal lines 261 and 263 is relatively large compared to the distance between two neighboring lower trench metal lines of the lower trench metal lines 151, 153 and 157 in which the parasitic capacitances C1 and C2 are generated, the parasitic capacitance C3 may be ignored during the operation of the semiconductor device.

The upper via barrier films 175 and 177 and the upper via seed films 255 and 257 remain only over the inside walls of the upper via holes 161 and 163, respectively. The upper via metal lines 261 and 263 are electrically connected to the lower trench metal lines 151 and 153 respectively.

The upper wiring insulating film 180 is formed over the upper interlayer insulating film 160 and the upper via metal lines 261, 263. The upper wiring insulating film 180 has upper trenches 181 and 183 therein for respectively exposing the upper via metal lines 261, 263 and for partially exposing the upper interlayer insulating film 160, and an upper trench 185 formed over the top of the lower trench metal line 157. An ashing process is performed over the resultant upper structure of the semiconductor substrate 100. Then, an upper trench barrier film 190 is formed over the upper via metal lines 261, 263 and the upper interlayer insulting film 160 exposed through the upper trench 181, 183 and 185. An upper trench seed film 200 and a fourth metal thin film 270 is subsequently formed over the upper trench barrier film 190.

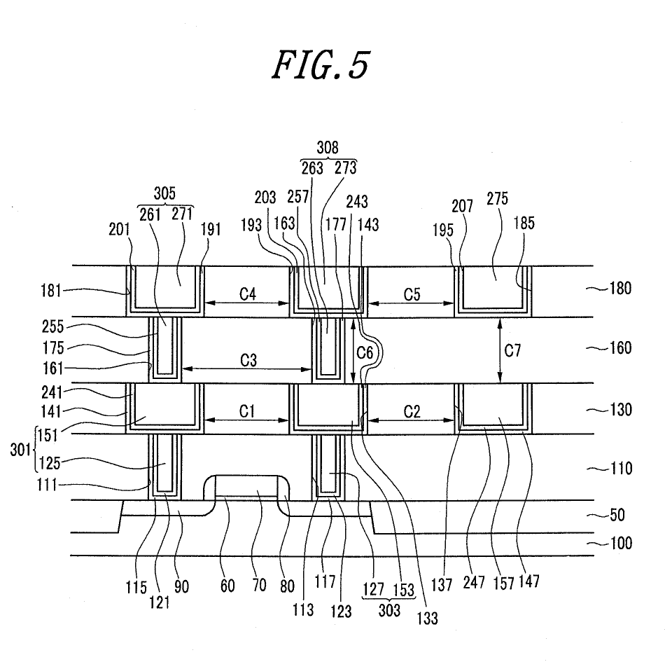

Then, as shown in FIG. 5, the CMP is carried out to remove the portions of the upper trench barrier film 190, the upper trench seed film 200 and a fourth metal thin film 270 which are positioned over the top of the upper wiring insulating film 180. The planarization process completes the upper trench metal lines 271, 273 and 275.

Two neighboring upper trench metal lines 271, 273 and 275 have parasitic capacitances C4 and C5. However, as described above, since low-K dielectric materials are used between the neighboring lower trench metal lines 271, 273 and 277, parasitic capacitances C4 and C5 are reduced and the operation of the semiconductor device is affected little.

Between the overlapping portions in which the lower trench metal lines 151, 153, 157 and the upper trench metal lines 271, 273, 275 are parasitic capacitances C6, C7 and C8. However, as described above, since the upper interlayer insulating film 160 which serves as the dielectric substance for the parasitic capacitances C6, C7 and C8 has a thickness of about 1,000 Å or more, the distances between the lower trench metal lines 151, 153 and 157 and the upper trench metal lines 271, 273 and 275 may be long enough to ignore their corresponding parasitic capacitances C6, C7 and C8 during the operation of the semiconductor device.

At this point, upper trench barrier films 191, 193, 195 and upper trench seed films 201, 203, 207 remain only over the inside walls of the upper trenches 181, 183 and 185.

The upper trench metal lines 271, 273 and the upper via metal lines 261, 263 are electrically connected to each other to form upper metal lines 305 and 308, respectively.

In accordance with embodiments, the via metal lines are first formed by the single damascene process and the trench metal lines which have widths wider than those of the via metal lines and are electrically connected with the via metal lines to form complete metal lines. In other words, the embodiments do not employ a process in which the dual damascene process is used to fill the inside of the via hole with a photoresist film and to form a trench. Therefore, the fences which could be formed due to the difference in the etching selectivity between the insulating film and the photoresist film filling the via hole are not formed over the bottom of the trench. Further, byproducts which could be generated by the removal of the photoresist film filling the inside of the via hole does not remain the insides of the via holes and the trenches of the embodiments. Accordingly, voids are not generated in the metal lines, which improves the electrical characteristics of the semiconductor device and reliability thereof.

Also, since the insulating film for surrounding and supporting the trench metal lines is made of a low-K material, for example SiO₂, the parasitic capacitance between neighboring trench metal lines may be minimized. Furthermore, the insulating film for surrounding and supporting the via metal lines is formed by depositing an insulating film with a thickness of about 1,000 Å or more, wherein the insulating film is made of SiO₂, FSG or the like. As a result, it is possible to minimize the parasitic capacitance which is generated between trench metal lines which overlap between layers, thereby allowing the operational speed of the semiconductor device to be increased.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first insulating film having a via hole on a semiconductor substrate, the substrate having a conductive layer;
forming a via metal line for filling the via hole;
forming, over the first insulating film, a second insulating film having a trench, the trench having a larger width than a width of the via hole; and
forming a trench metal line for filling the trench,
wherein the second insulating film is made of a low-K material, and the first insulating film is made of a different material from the second insulating film.

2. The method as claimed in claim 1, wherein the first insulating film has a thickness of at least 1,000 Å.

3. The method as claimed in claim 1, wherein the first insulating film includes at least one of FSG(fluoride-doped silicate glass), PSG(phosphorous-doped silicate glass), USG(undoped silicate glass), BPSG(boron phosphorous doped silicate glass) or silicon oxide material.

4. The method as claimed in claim 1, wherein the via metal line is exposed through the trench.

5. The method as claimed in claim 1, wherein the via metal line and the trench metal line are electrically connected to each other.

6. The method as claimed in claim 1, wherein the second insulating film is made of SiOC.

7. The method as claimed in claim 1, wherein the second insulating film is made of SiO₂.

8. The method as claimed in claim 1, wherein forming a via metal line for filling the via hole comprises forming a barrier layer.

9. The method as claimed in claim 1, wherein forming a via metal line for filling the via hole comprises forming a seed layer.

10. The method as claimed in claim 1, wherein forming a trench metal line for filling the trench comprises forming a barrier layer.

11. The method as claimed in claim 1, wherein forming a trench metal line for filling the trench comprises forming a seed layer.

12. The method as claimed in claim 1, wherein forming a via metal line for filling the via hole comprises a chemical mechanical polishing (CMP) process.

13. The method as claimed in claim 1, wherein forming a trench metal line for filling the trench comprises a chemical mechanical polishing (CMP) process.
